(19) United States
(12) Patent Application Publication
(10) Pub. No.: US 2007/0235177 A1
(43) Pub. Date: Oct. 11, 2007

(54) Heat conducting medium protection device

(76) Inventors: Feng-Ku Wang, Taipei (TW); Yi-Lun Cheng, Taipei (TW); Jui-Chan Fan, Taipei (TW); Chun-Yi Chang, Taipei (TW); Chun-Lung Lin, Taipei (TW); Chih-Kai Yang, Taipei (TW)

Correspondence Address: HARNESS, DICKEY & PIERCE, P.L.C., P.O. BOX 8910, RESTON, VA, 20195, US

(21) Appl. No.: 11/399,454

(22) Filed: Apr. 7, 2006

(51) Int. Cl. H05K 7/20

(52) U.S. Cl. 165/185; 361/705

(57) ABSTRACT

A heat conducting medium protection device is provided. At least one cutout is formed in a sheet, and the sheet is bent to closely engage the cutouts so as to transform the sheet into a three-dimensional shape and form an accommodating space. When the heat conducting medium protection device is covered on a heat sink coated with a heat conducting medium, the accommodating space accommodates the heat conducting medium for holding the heat conducting medium, thereby making it easy to transmit the heat sink coated with a heat conducting medium.

### BACKGROUND OF THE INVENTION

1. Field of Invention

The present invention relates to a heat conducting medium protection device, and more particularly to a heat conducting medium protection device applied to a heat sink already coated with a heat conducting medium.

2. Related Art

In general, a heat sink is used when a heat-generating element is at work. The heat sink transfers the heat generated by the heat-generating element to the outside to reduce the temperature of the heat-generating element, so as to enable the heat-generating element to operate normally. However, to improve the heat conduction efficiency between the heat sink and the heat-generating element, a heat conducting medium which is of a high heat conductive material is usually taken as a medium, so that the heat dissipation efficiency can be improved by disposing the heat conducting medium between the heat-generating element and the heat sink.

However, for convenience of assembly, the heat conducting medium is first coated onto the heat sink; as such, the heat sink can be directly connected to the heat-generating element, without the additional step of coating the heat conducting medium. However, it may cause inconvenience when transporting the heat sink, due to problems, such as that the heat conducting medium is detached from the heat sink, or the coating area of the heat conducting medium is enlarged may occur during the transit or conveying process, therefore, a holding protection should be made for the heat conducting medium.

The related art, for example, U.S. Pat. No. 5,897,917, discloses a protective film directly attached to the bottom surface of a heat sink coated with a heat conducting medium, for protecting the heat conducting medium. The method can prevent the heat conducting medium and the surrounding environment from contaminating each other, however, the protective film directly attached to the heat conducting medium is easily deformed under the pressure of external forces applied from the surrounding environment or scratched during transportation of the heat sink.

U.S. Pat. No. 6,049,458 discloses a heat conducting medium protective cover. A heat sink coated with a heat conducting medium is correspondingly disposed under the middle of the cover. The edge of the cover is fixed onto the bottom surface of the heat sink by means of adhesion. While the method can alleviate the problem of the heat conducting medium being deformed under pressure or being scratched, it is common to have the adhesive substance remain on the surface of the heat sink when the cover is removed, resulting in an uneven surface of the heat sink and requiring additional work to clear away the adhesive substance, thereby greatly affecting the heat sink effect. Besides, it is difficult for the protective cover to be tightly fixed onto the surface of the heat sink due to poor adhesion, so the protective cover easily falls off, resulting in the loss of its function for protecting the heat conducting medium. Moreover, the structure of the protective cover is complicated, and thereby the cost is increased.

### SUMMARY OF THE INVENTION

In view of the above, a main object of the invention is to provide a heat conducting medium protection device, for forming an accommodating space by bending the sheet. When the heat conducting medium protection device is fixed onto the heat sink, the accommodating space can be used to accommodate the heat conducting medium for holding the heat conducting medium, thereby preventing displacement of the heat conducting medium and preventing the heat conducting medium from being detached from the heat sink during conveying of the heat sink.

Therefore, to achieve the above object, the heat conducting medium protection device disclosed by the invention is covered on the heat sink coated with a heat conducting medium, for preventing the heat conducting medium from being deformed, and making it easy to convey the heat sink coated with a heat conducting medium. Thus, in the heat conducting medium protection device of the invention, at least one cutout is formed in a sheet, and the sheet is bent to closely engage the cutout for transforming the sheet into a three-dimensional shape, so as to form an accommodating space to hold the heat conducting medium by accommodating it when the heat conducting medium protection device is covered onto the heat sink.

An opening is formed on the sheet, so as to reduce the air resistance during movement of the sheet.

Moreover, as the heat conducting medium protection device is transformed into a three-dimensional shape by being bent, the cutout can be closely engaged via an adhesive or adhesive tape for forming the three-dimensional shape. Besides, a sheet of metal material can also be adopted, and the sheet can maintain in a three-dimensional shape in a normal state after being bent.

When the heat sink is connected to a heat-generating element, the heat conducting medium protection device has to be removed. Therefore, a protrusion is further disposed at one side of the sheet, for making it easy to detach the heat conducting medium protection device from the heat sink when applying a force to the protrusion.

Therefore, the heat conducting medium protection device of the invention can be transformed into a three-dimensional shape by bending the sheet, and being provided with an accommodating space for holding the heat conducting medium. Besides, the heat conducting medium protection device is integrated as one piece, so it is quite simple and fast no matter whether with regard to fabrication, processing, or material handling.

The features and practices of the present invention will be illustrated in detail below through preferred embodiments accompanied with drawings.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and which thus is not limitative of the present invention, and wherein:

FIG. 1 is a combined diagram of the invention;

FIG. 2 is an exploded view of the invention;

FIGS. 3A and 3B are schematic views of the heat conducting medium protection device according to the invention;

FIG. 4A is a schematic view of the heat conducting medium protection device according to the invention, wherein the cutouts are closely engaged via an adhesive;

FIG. 4B is a schematic view of the heat conducting medium protection device according to the invention, wherein the cutouts are closely engaged via an adhesive tape;

FIGS. 5A and 5B are schematic views of the heat conducting medium protection device according to a second embodiment of the invention;

FIG. 5C is a combined diagram of the second embodiment of the invention.

### DETAILED DESCRIPTION OF THE INVENTION

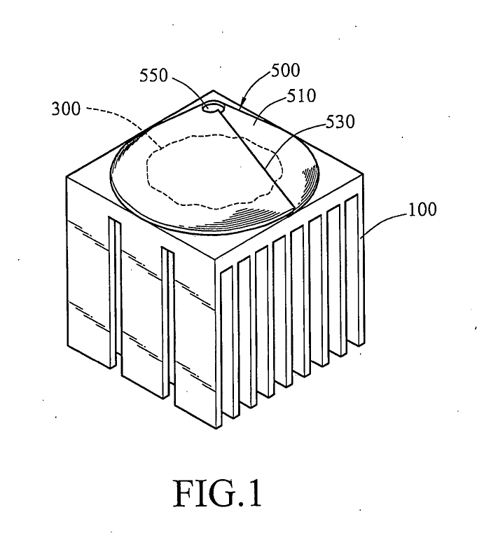

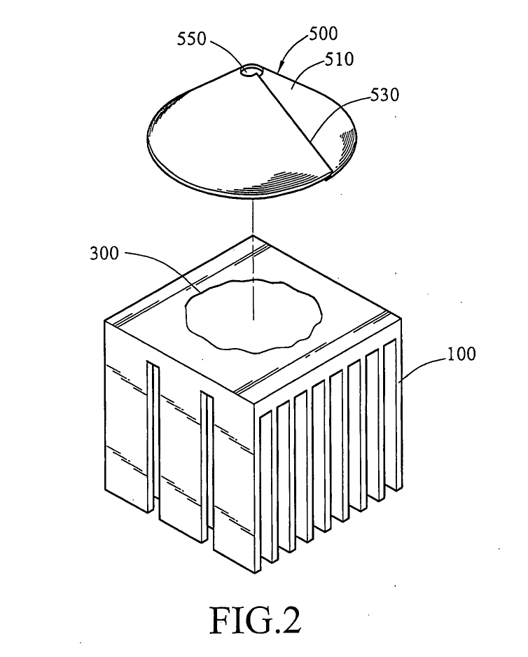

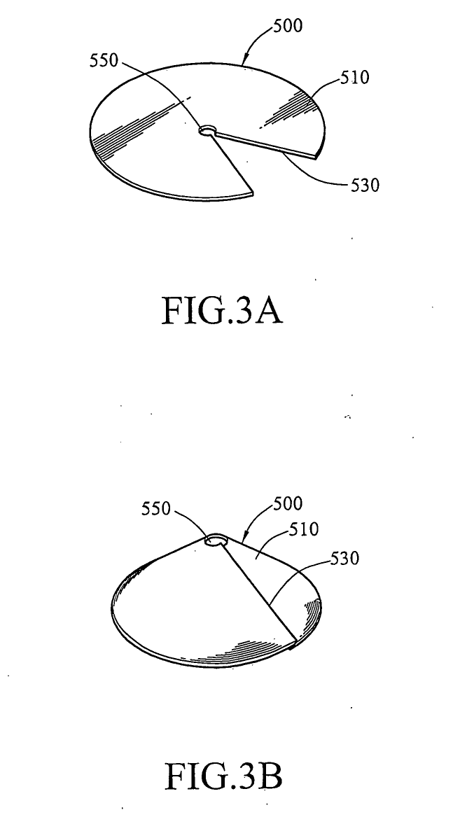

Referring to FIGS. 1, 2, and 3A, a combined diagram and an exploded view of the invention, as well as a schematic view of the heat conducting medium protection device of the invention are depicted. A heat conducting medium protection device 500 applied to a heat sink 100 already coated with a heat conducting medium 300, for holding the heat conducting medium 300. In the heat conducting medium protection device 500, a fan-shaped cutout 530 is formed along the radial direction of a disc sheet 510. Then, the disc sheet 510 is bent to closely engage the fan-shaped cutout 530, so as to make the disc 510 appear in a cone shape as shown in FIG. 3B. An accommodating space is formed at one side, for accommodating and holding the heat conducting medium 300 when the coniform disc sheet 510 is covered onto the heat sink 100. Therefore, during the conveying of the heat sink 100, as the heat conducting medium 300 is limited by the accommodating space formed by the disc sheet 510 after being bent, its original form can be maintained.

An opening 550 is formed in the fan-shaped cutout 530 in the middle of the disc 510, for making the fan-shaped cutout 530 smoothly engaged as a cone when the disc sheet 510 is bent. Besides, the opening 550 can also make the air in the accommodating space escape from the disc 510 via the opening 550 when the bent disc sheet 510 is being covered onto the heat sink 100, so as to reduce the air resistance when the disc sheet 510 is connected to the heat sink 100.

Furthermore, the disc sheet 510 can be connected to the heat sink 100 via an adhesive or a double-sided adhesive tape.

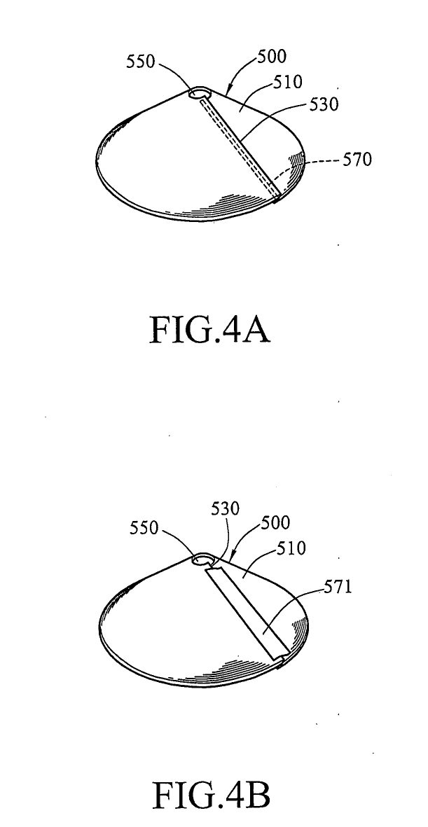

Moreover, after the disc sheet 510 is bent to closely engage the fan-shaped cutout 530, the cutout 530 can be closely engaged by using an adhesive 570 or an adhesive tape 571 as shown in FIGS. 4A and 4B, or by heating the cutout till the material is melt and then engaging the cutout. If the material for the disc sheet 510 is a metal material, the disc sheet 510 can be maintained as a cone via permanent deformation after being bent. Or, fasteners (not shown) disposed at the cutout are used to closely engage the cutout by fastening the fasteners.

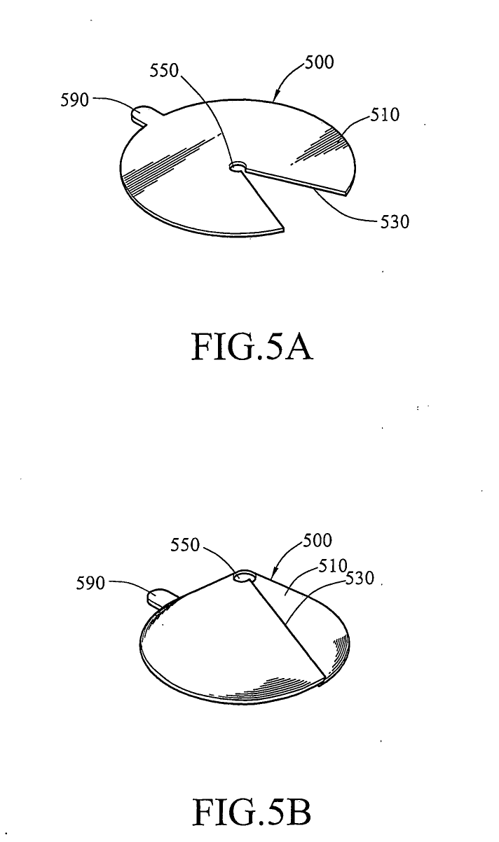

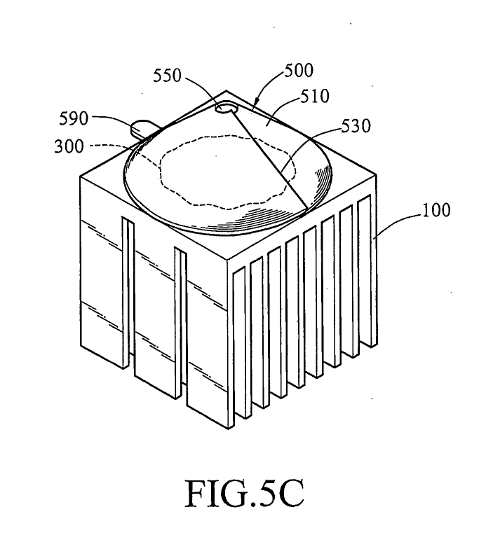

Referring to FIGS. 5A, 5B, and 5C, schematic views and a combined diagram of the heat conducting medium protection device according to a second embodiment of the invention are depicted. A protrusion 590 is further disposed on the circumference surface of the disc sheet 510, for making it easy to detach the heat conducting medium protection device 500 connected to the heat sink 100. When the heat sink 100 is to be connected to a heat-generating element (not shown), the heat conducting medium protection device 500 has to be removed from the heat sink 100, thus the heat conducting medium protection device 500 can be detached from the heat sink 100 by applying a force on the protrusion 590. Therefore, the protrusion 590 functions as the force application position for removing the heat conducting medium protection device 500.

The heat conducting medium protection device of the invention can form an accommodating space for holding the heat conducting medium by simply bending a sheet, thus the fabricating cost is reduced and process convenience is improved. Moreover, the heat sink protection device can be reused repeatedly, thus it is advantageous for environmental protection.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A heat conducting medium protection device, covered onto a heat sink coated with a heat conducting medium, wherein the heat conducting medium protection device is a sheet, and at least one cutout is formed in the sheet, and the cutout is closely engaged by bending the sheet to transform the sheet into a three-dimensional shape, and an accommodating space is formed to accommodate the heat conducting medium.

2. The heat conducting medium protection device as claimed in claim 1, wherein the sheet is a disc sheet.

3. The heat conducting medium protection device as claimed in claim 2, wherein a fan-shaped cutout is formed in the disc sheet along the radial direction, after the disc sheet is bent, the fan-shaped cutout is closely engaged.

4. The heat conducting medium protection device as claimed in claim 2, wherein an opening is formed in the fan-shaped cutout in the middle of the disc sheet, for making the fan-shaped cutout smoothly engaged.

5. The heat conducting medium protection device as claimed in claim 2, wherein the disc sheet is connected to the heat sink via an adhesive.

6. The heat conducting medium protection device as claimed in claim 2, wherein the disc sheet is connected to the heat sink via a double-sided adhesive tape.

7. The heat conducting medium protection device as claimed in claim 2, wherein the fan-shaped cutout is closely engaged via an adhesive.

8. The heat conducting medium protection device as claimed in claim 2, wherein the fan-shaped cutout is closely engaged via a double-sided adhesive tape.

9. The heat conducting medium protection device as claimed in claim 2, wherein the material for the disc sheet is a metal material, for maintaining a cone in a normal state after the disc sheet is bent.

10. The heat conducting medium protection device as claimed in claim 2, wherein a protrusion is further disposed on the circumference surface of the disc sheet, for making the heat conducting medium protection device detached from the heat sink when applying a force to the protrusion.

11. The heat conducting medium protection device as claimed in claim 1, wherein an opening is formed in the sheet for reducing the air resistance when moving the sheet.

12. The heat conducting medium protection device as claimed in claim 1, wherein the material for the sheet is a metal material for maintaining the three-dimensional shape in a normal state after the sheet is bent.

13. The heat conducting medium protection device as claimed in claim 1, wherein a protrusion is further disposed at one side of the sheet, for making the heat conducting medium protection device detached from the heat sink when applying a force to the protrusion.

14. The heat conducting medium protection device as claimed in claim 1, wherein the cutout is closely engaged via an adhesive.

15. The heat conducting medium protection device as claimed in claim 1, wherein the cutout is closely engaged via a double-sided adhesive tape.
